(19) United States
(12) Patent Application Publication
(10) Pub. No.: US 2019/0252331 A1
(43) Pub. Date: Aug. 15, 2019

(54) HIGH-VOLTAGE CAPACITOR STRUCTURE AND DIGITAL ISOLATION APPARATUS

(71) Applicant: VOLTRON MICROELECTRONICS CORP., Hsinchu County (TW)

(72) Inventor: CHUN-YI CHENG, Hsinchu Country (TW)

(21) Appl. No.: 15/964,955

(22) Filed: Apr. 27, 2018

(30) Foreign Application Priority Data
Feb. 13, 2018 (TW) 107105179

(51) Int. Cl. H01L 23/66; H01P 1/36; H01L 29/06; H01L 23/31; H01L 49/02; H01L 27/06

(52) U.S. Cl. CPC H01L 23/66; H01P 1/36; H01L 29/0649; H01L 23/3171; H01L 2223/6661; H01L 29/0684; H01L 27/0611; H01L 2223/6611; H01L 2223/6638; H01L 28/60

(57) ABSTRACT

A high-voltage capacitor structure comprises a capacitor. The capacitor includes a substrate, a field oxidation layer, an active region, a dielectric layer, a passivation layer and a metal layer. The field oxidation layer is disposed above the substrate. The active region is disposed above the substrate or in the substrate. The dielectric layer is disposed above the active region and the field oxidation layer. The passivation layer is disposed above the dielectric layer. The metal layer is disposed above the passivation layer. The metal layer and the active region serve as a first electrode and a second electrode of the capacitor, respectively, wherein the active region is disposed below the dielectric layer. Some embodiments provide a digital isolation apparatus comprising at least one high-voltage isolator, each of which includes the above high-voltage capacitor structure.

### CROSS-REFERENCE TO RELATED APPLICATION

This non-provisional application claims priority under 35 U.S.C. § 119(a) on Patent Application No. 107105179 filed in Taiwan, R.O.C. on Feb. 13, 2018, the entire contents of which are hereby incorporated by reference.

### TECHNICAL FIELD

The present disclosure relates to a high-voltage capacitor structure, and in particular to a high-voltage capacitor structure with reduced complexity and a digital isolation apparatus having the high-voltage capacitor structure.

### RELATED ART

The voltage that a high-voltage capacitor isolator can withstand is determined by a distance between an upper plate and a lower plate of a capacitor. The smaller the distance between the upper plate and the lower plate of the capacitor, the lower the voltage that can be withstood by the capacitor. Conversely, the greater the distance between the upper plate and the lower plate of the capacitor, the higher the voltage that can be withstood by the capacitor.

In order to realize the high-voltage isolation and high-withstanding-voltage capacitor, it is conventional to use metal-insulator-metal (MIM) capacitors. As mentioned above, the larger the distance between the upper plate and the lower plate of the capacitor, the greater the withstanding voltage. Thus, the distance between the upper plate and the lower plate of the capacitor can be increased in order to achieve the object of a high-voltage capacitor isolator with a withstanding voltage to be required.

However, a typical process cannot directly form a thick inter-metal dielectric layer. Overlaying of many inter-metal dielectric layers is required to increase the withstanding voltage of the capacitor when high-voltage withstanding capability is needed. Referring to FIG. 1, a conventional high-voltage capacitor structure is shown in a cross-sectional view. As shown in FIG. 1, a capacitor 10 includes a substrate 100, a field oxidation layer 101, an inter-layer dielectric layer 102, a metal layer 110, inter-metal dielectric layers 111 to 115, a metal layer 116, a passivation layer 117, wherein a bonding wire 120 may be disposed on the metal layer 116 for connection to an external circuit. When the approach as shown in FIG. 1 is adopted, a multi-layer metal process needs to be selected. As shown in FIG. 1, although the internal circuit of the capacitor 10 only needs two-metal layers, the process of six-metal layers (M6) or the process of more metal layers is required if the high withstanding voltage of the high-voltage capacitor needs to be achieved, so the complexity of manufacturing the isolator will be greatly increased, and the production efficiency will be reduced, while the production costs will increase.

Therefore, it is desirable to improve the conventional approach that employs the MIM capacitor to realize the high-voltage isolation and high withstanding voltage capacitor, so as to reduce the complexity of the manufacturing process and improve the production efficiency.

### SUMMARY

An objective of the present disclosure is to provide a high-voltage isolation and withstanding capacitor structure that can be implemented by using lower-complexity process, thus improving the manufacturing efficiency.

To achieve at least the above objective, the present disclosure provides a high-voltage capacitor structure comprises a capacitor. The capacitor includes a substrate, a field oxidation layer, an active region, a dielectric layer, a passivation layer and a metal layer. The field oxidation layer is disposed above the substrate. The active region is disposed above the substrate or in the substrate. The dielectric layer is disposed above the active region and the field oxidation layer. The passivation layer is disposed above the dielectric layer. The metal layer is disposed above the passivation layer. The metal layer and the active region serve as a first electrode and a second electrode of the capacitor, respectively, wherein the active region is disposed below the dielectric layer.

In an embodiment, the field oxidation layer has at least one opening, and the active region is disposed in a location of the substrate corresponding to the opening.

In an embodiment, the active region is a well region in the substrate, the well region has a dopant impurity of a first conductivity type, the substrate is a substrate of a second conductivity type, and the first conductivity type is opposite to the second conductivity type.

In an embodiment, the high-voltage capacitor structure further includes a signal electrode electrically connected to the active region.

In an embodiment, the dielectric layer is a first dielectric layer, the high-voltage capacitor structure further includes a second dielectric layer, and the second dielectric layer is disposed above the first dielectric layer.

In an embodiment, the dielectric layer is an inter-metal dielectric layer or inter-layer dielectric layer.

In an embodiment, the passivation layer has a thickness greater than that of the dielectric layer.

In an embodiment, the metal layer has a thickness of greater than 2 μm.

To achieve at least the above objective, the present disclosure further provides a digital isolation apparatus comprising at least one high-voltage isolator, each of which includes a high-voltage capacitor structure as in any one of the above embodiments.

In an embodiment, the number of the at least one high-voltage isolator included in the digital isolation apparatus is plural, and at least two of the high-voltage isolators are provided for transmission of differential signals.

As such, a high-voltage isolation and withstanding capacitor structure may be implemented based on any of the above embodiments of the high-voltage capacitor structure by using lower-complexity process, thus improving the manufacturing efficiency and design flexibility, and reducing the production cost. The high-voltage capacitor structure may be further integrated in a digital isolation apparatus, such that the digital isolation apparatus can be implemented with greatly reduced manufacturing complexity, improved production efficiency and design flexibility, and reduced production cost.

### BRIEF DESCRIPTION OF THE DRAWINGS

FIG. 1 (prior art) is a cross-sectional view schematically illustrating a conventional high-voltage capacitor structure;

FIG. 2A is a cross-sectional view schematically illustrating a high-voltage capacitor structure according to an embodiment of the disclosure;

FIG. 2B is a cross-sectional view schematically illustrating a high-voltage capacitor structure according to another embodiment of the disclosure;

FIG. 2C is a cross-sectional view schematically illustrating a high-voltage capacitor structure according to another embodiment of the disclosure;

FIG. 2D is a cross-sectional view schematically illustrating a high-voltage capacitor structure according to another embodiment of the disclosure;

FIG. 3 is a cross-sectional view schematically illustrating an embodiment of the active region and field oxidation layer;

FIG. 4 is a cross-sectional view schematically illustrating a portion of the manufacturing process for the active region in FIG. 3 according to an embodiment;

FIG. 5 is a schematic block diagram illustrating an embodiment of a digital isolation apparatus having a high-voltage isolator;

FIG. 6 is a schematic block diagram illustrating an embodiment of a digital isolation apparatus having high-voltage isolators;

FIG. 7 is a schematic block diagram illustrating an embodiment of a digital isolation apparatus having high-voltage isolators;

FIG. 8 is a schematic block diagram illustrating an embodiment of a digital isolation apparatus having high-voltage isolators; and

FIG. 9 is a schematic block diagram illustrating an embodiment of a digital isolation apparatus having high-voltage isolators.

### DETAILED DESCRIPTION OF THE PREFERRED EMBODIMENTS

To make the objects, characteristics and effects of the present disclosure readily to be understood, embodiments together with the attached drawings for the detailed description of the present disclosure are provided.

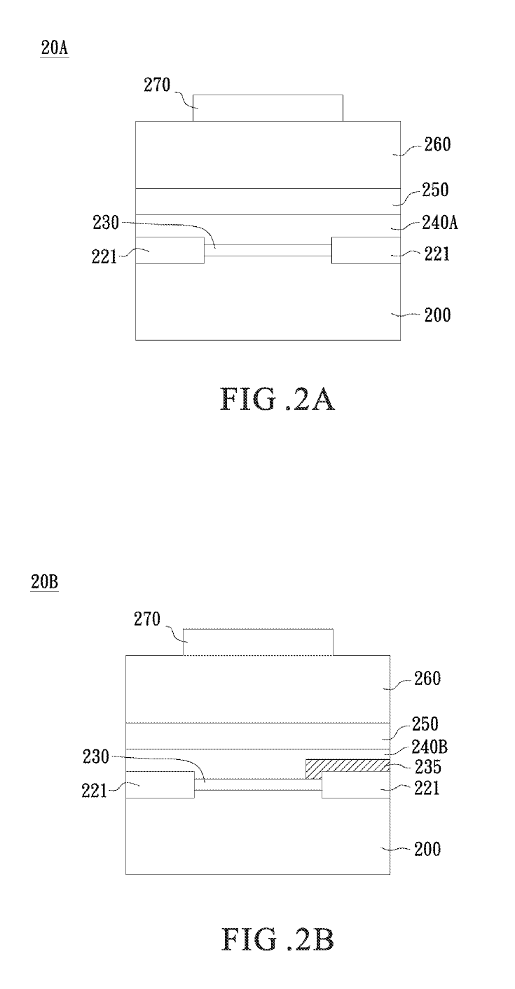

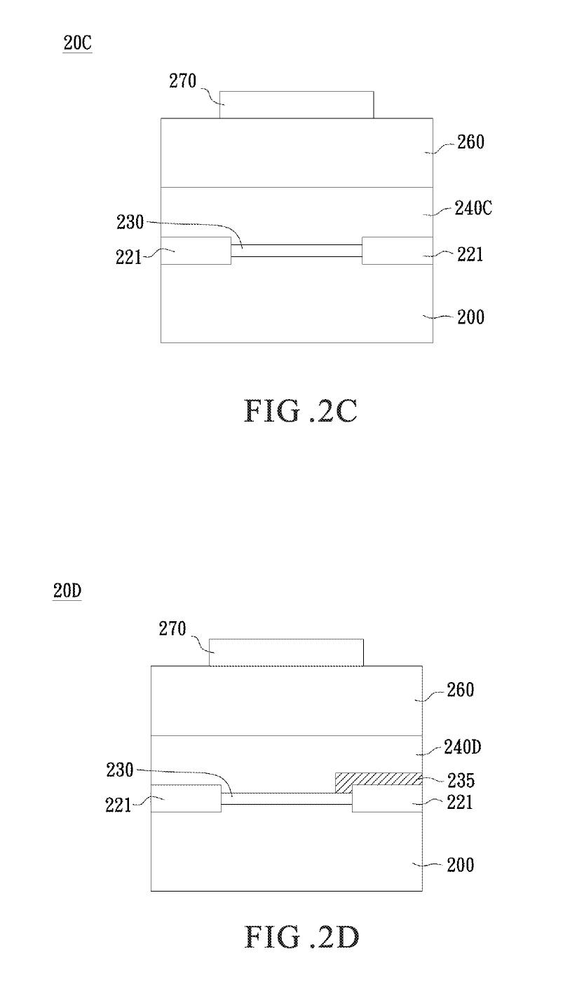

Referring to FIG. 2A, a cross-sectional view illustrates a high-voltage capacitor structure according to an embodiment schematically. As shown in FIG. 2A, the high-voltage capacitor structure includes a capacitor 20A. The capacitor 20A includes a substrate 200, a field oxidation layer 221, an active region 230, a first dielectric layer 240A, a second dielectric layer 250, a passivation layer 260, and a metal layer 270. The active region 230 is disposed in the substrate 200 or above substrate 200 and located below the first dielectric layer 240A. For example, the active region 230 may be implemented as a well region in the substrate 200, or the active region 230 may be disposed above a portion of the substrate 200 corresponding to an opening of the field oxidation layer 221. The field oxidation layer 221 is disposed above substrate 200. The first dielectric layer 240A is disposed above the active region 230 and the field oxidation layer 221. The second dielectric layer 250 is disposed above the first dielectric layer 240A. The passivation layer 260 is disposed above the second dielectric layer 250. The metal layer 270 is disposed above the passivation layer 260. The metal layer 270 and the active region 230 serve as a first electrode and a second electrode of the capacitor 20A, respectively. The active region 230 is located under or below the first dielectric layer 240A and the second dielectric layer 250.

In addition, as shown in FIG. 2B, an embodiment based on the high-voltage capacitor structure of FIG. 2A may further include a signal electrode 235, which is electrically connected to the active region 230. For example, the signal electrode 235 may be configured to be in contact with the active region 230 and extended above the field oxidation layer 221 (e.g., above one side or two sides of the field oxidation layer 221). The signal electrode 235 may be utilized to facilitate the second electrode of the capacitor 20B (i.e., the active region 230) for signal receiving or transmission, or for connection to a component or circuit external to the capacitor 20B. In implementation for the signal electrode, for example, a metal layer may be formed on the field oxidation layer 221 and is made to be in contact with the active region 230, or a conventional contact process may be adopted. However, the implementation of the invention is not restricted to the examples, and any appropriate approach may be employed to implement the signal electrode, regardless of whether the signal electrode is extended above the field oxidation layer 221 or the manufacturing process.

Referring to FIG. 2C, a cross-sectional view illustrates a high-voltage capacitor structure according to another embodiment. As shown in FIG. 2C, the high-voltage capacitor structure of the embodiment includes a capacitor 20C. The capacitor 20C in FIG. 2C and the capacitor 20A in FIG. 2A have a similar structure. The capacitor 20C differs mainly from the capacitor 20A in that the capacitor 20C utilizes a dielectric layer 240C, instead of the first dielectric layer 240A and the second dielectric layer 250 of FIG. 2A. In this manner, the capacitor 20C can be simplified in respect of structure and manufacturing process.

Referring to FIG. 2D, a cross-sectional view illustrates a high-voltage capacitor structure according to a further embodiment. As shown in FIG. 2D, the high-voltage capacitor structure of the embodiment includes a capacitor 20D. The capacitor 20D in FIG. 2D is similar to the capacitor 20B in FIG. 2B in structure. The capacitor 20D differs mainly from the capacitor 20B in that the capacitor 20D utilizes a dielectric layer 240D instead of the first dielectric layer 240B and the second dielectric layer 250 of FIG. 2B. In this manner, the capacitor 20D can be simplified in respect of structure and manufacturing process.

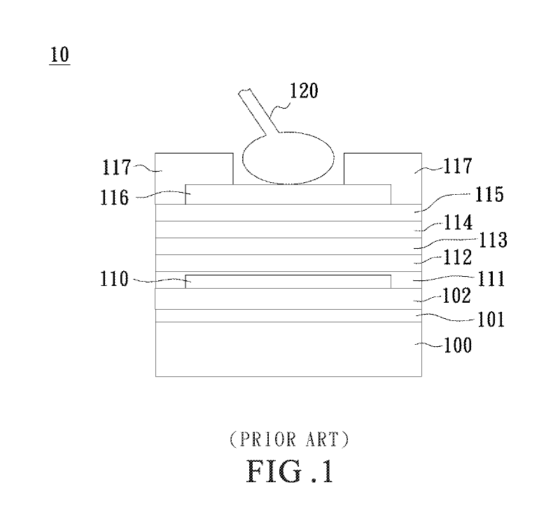

In any one of the high-voltage capacitor structures as shown in FIGS. 2A to 2D, the capacitor (such as 20A, 20B, 20C or 20D) takes the metal layer 270 as the first electrode and the metal layer 270 is disposed above the passivation layer 260. Hence, the high-voltage withstanding capability of the capacitor can be enhanced by way of an increase in the thickness of the passivation layer 260. In addition, compared to the conventional capacitor 10 in FIG. 1, the capacitor of any of the above embodiments employs the active region 230 as the second electrode and has one or more dielectric layers (such as dielectric layer 240C, 240D, or the first dielectric layer 240A or 240B and the second dielectric layer 250) disposed above the active region 230, thereby enhancing the high-voltage withstanding capability of the capacitor. Compared to the conventional capacitor 10 in FIG. 1, any of the configurations in FIGS. 2A to 2D can be fulfilled by using manufacturing processes for metal layers of lower levels (such as the second metal layer M2 or the third metal layer M3 and so on), instead of manufacturing processes for metal layers of higher levels, and by using overlaying with a reduced number of dielectric layer, so as to decrease the complexity of the capacitor structure.

A high-voltage isolation and withstanding capacitor structure may be implemented based on any of the above embodiments of the high-voltage capacitor structure by using lower-complexity process, thus improving the manufacturing efficiency and design flexibility, and reducing the production cost. For example, the embodiments of the high-voltage capacitor structure may be implemented by a low-level process, achieving the voltage withstanding requirement that can only be achieved by the capacitor structure that requires the overlaying of multiple dielectric layers and higher levels of metal layers. Thus, the above-described embodiments of the high-voltage capacitor structure utilize the structural arrangement to obtain the enhancement of the voltage withstanding capability and the flexibility of implementation. In this manner, high-voltage withstanding capacitor structures may be readily implemented on the integrated circuit so that the flexibility and production efficiency of the integrated circuit design can be improved and the cost can be reduced.

For example, the capacitor structure of any of the above embodiments may be configured to function as a high-voltage capacitor. The term of high voltage may be defined as any voltage in a range of 50V to 5000V. In practice, the capacitor may be configured for a specific operating voltage range according to product specifications or design requirements. For example, the operating voltage range may be 800V or less, 1000V or less, 2000V or less, 4000V or less, 5000V or less, or other selected voltage range. However, the implementation of the invention is not limited to these examples. For example, the structure of the capacitor may be configured to operate above 5000V.

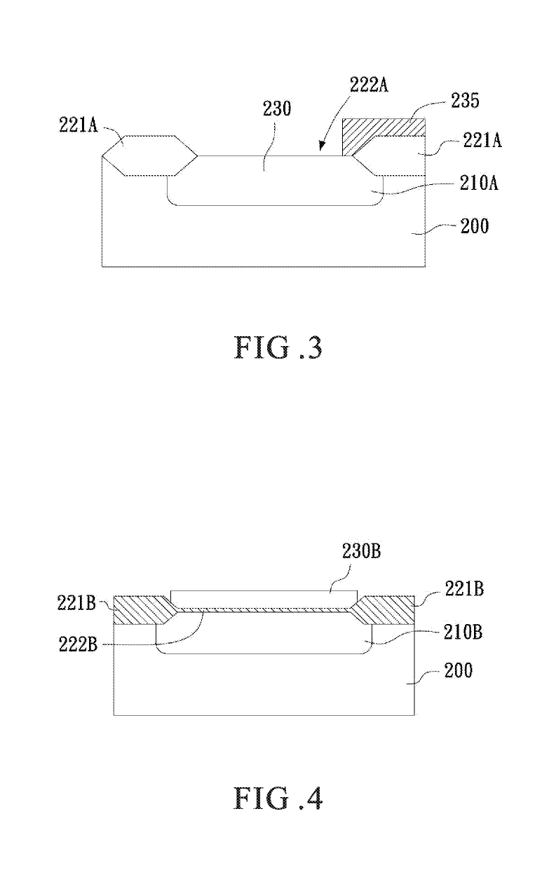

Referring to FIG. 3, a cross-sectional view illustrates an embodiment of the active region 230 and the field oxidation layer 221, which may be applied to the implementation of the high-voltage capacitor structure as shown in any one from FIGS. 2A to 2D. As shown in FIG. 3, in this embodiment, the field oxidation layer 221 includes at least two separated portions 221A and at least one opening 222A, and the active region 230 is disposed at a location of the substrate 200 corresponding to the opening 222A. The active region 230 may be a well region 210A which has a dopant impurity of a first conductivity type and the substrate 200 is a substrate of a second conductivity type, wherein the first conductivity type is opposite to the second conductivity type. In addition, the signal electrode 235 may be configured to be electrically connected to the active region 230, as shown in FIG. 3.

FIG. 4 is a cross-sectional view schematically illustrating a portion of the manufacturing process for the active region in FIG. 3 according to an embodiment. As shown in FIG. 4, in this embodiment, the field oxidation layer 221 has a plurality of first portion 221B and at least one second portion 222B, the second portion 222B is disposed between two adjacent first portions 221B, the second portion 222B has a thickness less than that of the first portion 221B. In this embodiment, a patterned mask 230B for active region is disposed above the second portion 222B and the well region 210B is disposed in the substrate 200 and below the second portion 222B. In addition, the well region 210B has a dopant impurity of the first conductivity type and the substrate 200 is of the second conductivity type. The patterned mask 230B for active region as shown in FIG. 4 may be removed by way of physical or etching process, so as to form the active region 230 in FIG. 3. After that, the signal electrode 235 may be further formed to be electrically connected to the active region 230, as shown in FIG. 3. However, the implementation of the invention is not restricted to the examples.

Based on the embodiment of FIG. 3 or 4, the substrate 200 may be implemented as a p-type substrate, and the well region 210A or 210B may be implemented as an n-type doped well region. Alternatively, the substrate 200 may be implemented as an n-type substrate, and the well region 210A or 210B may be implemented as a p-type doped well region.

In some embodiments based on the capacitor of any one of the high-voltage capacitor structures from FIGS. 2A to 2D, an active region 230 may be formed on a portion of the substrate 200 which corresponds to an opening of the field oxidation layer 221, without needing to form the well region.

In the embodiment of FIG. 2A or 2B, the first dielectric layer 240A (or 240B) may be an inter-layer dielectric (ILD) layer or inter-metal dielectric (IMD) layer. The second dielectric layer 250 may be an ILD layer or IMD layer.

In the embodiment of FIG. 2C or 2D, the dielectric layer 240C (or 240D) may be an IMD layer or ILD layer.

In an embodiment, the passivation layer 260 has a thickness greater than a sum of thickness of the first dielectric layer 240A (or 240B) and the second dielectric layer 250. For example, the passivation layer 260 has a thickness of 5 μm, the first dielectric layer 240A (or 240B) and the second dielectric layer 250 have thicknesses of 1 μm, respectively. In an embodiment, the passivation layer 260 has a thickness greater than that of the dielectric layer 240C or 240D.

In addition, for example, in order to increase the withstanding voltage of the dielectric layer of the high-voltage capacitor, the passivation layer 260, and at least one dielectric layer (such as dielectric layer 240C, 240D, the first dielectric layer 240A or 240B, the second dielectric layer 250) may be configured to have suitable thicknesses according to the capacitance value of the capacitor (such as 20A, 20B, 20C or 20D) to be achieved in practice. For example, the sum of the thicknesses of the first dielectric layer 240A (or 240B), the second dielectric layer 250, the passivation layer 260 may be set to about 5 μm to 15m. However, the implementation of the invention is not restricted by these examples. For example, the sum of the above thicknesses may also be about 5 μm or less.

In an embodiment, the metal layer 270 may be configured to have a thickness of greater than 2 μm. However, the implementation of the invention is not restricted by these examples. For example, the thickness of the metal layer 270 may be configured to about 1 to 2 μm or less than 2 μm.

In addition, in some embodiments, dielectric layer 240C, 240D, the first dielectric layer 240A or 240B, or the second dielectric layer 250 may be implemented by using any suitable dielectric layer material, such as a-Si, poly-Si, silicon oxide, silicon nitride, low-k material, or any material suitable for subsequent stages of processes. However, the implementation of the invention is not restricted by these examples. Further, in some other embodiments, at least one dielectric layer may be further disposed between the active region 230 and the passivation layer 260 of the capacitor in FIG. 2A or FIG. 2B to further increase the voltage withstanding capability of the capacitor.

In addition, a digital isolation apparatus may be implemented based on any one of the above embodiments of the high-voltage capacitor structure. In this manner, the digital isolation apparatus may be implemented with greatly reduced manufacturing complexity, improved production efficiency and design flexibility, and reduced production cost. For example, a high-voltage isolator may be realized by utilizing the above high-voltage capacitor structure as a high-voltage isolator and configuring the first electrode and second electrode of the high-voltage capacitor structure. For instance, the high-voltage isolator may have a signal input end and a signal output end, wherein the signal input end is made by using a bonding wire connected to the metal layer 270 and the signal output end is made by connecting a bonding wire to a signal electrode electrically connected to the active region 230. Further, a high-voltage isolator may be implemented by using two or more capacitors, based on any one of FIGS. 2A to 2D, electrically coupled in series or parallel. A digital isolation apparatus may be further implemented by using a high-voltage isolator having the high-voltage capacitor structure. The digital isolation apparatus comprises at least one high-voltage isolator, and each high-voltage isolator may include any one of the above embodiments of the high-voltage capacitor structure so as to transmit signals. In an embodiment, the number of the at least one high-voltage isolator included in the digital isolation apparatus is plural, and at least two of the high-voltage isolators are provided for transmission of differential signals.

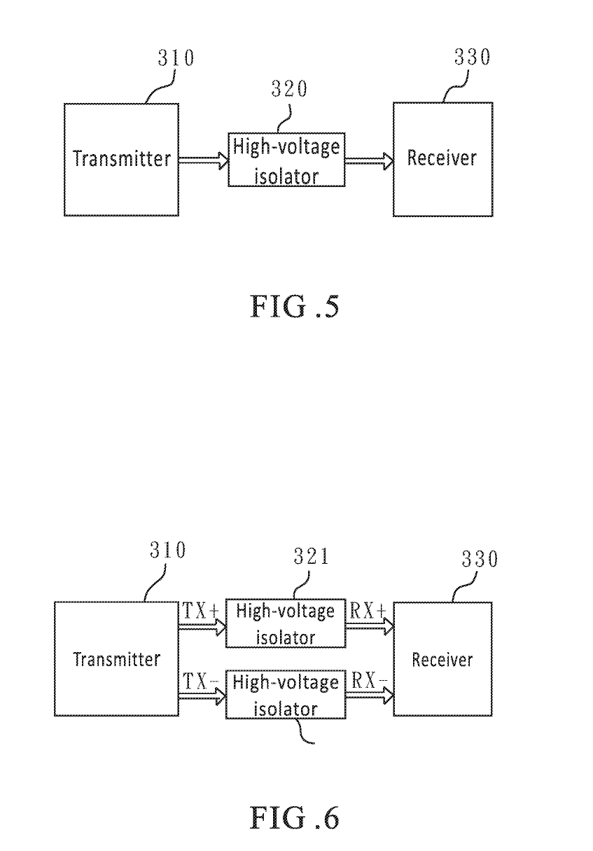

Referring to FIGS. 5 to 9, the block diagrams schematically illustrate embodiments of the high-voltage isolator of the digital isolation apparatus.

As shown in FIG. 5, a digital isolation apparatus includes a transmitter (TX) 310, a high-voltage isolator 320 and a receiver (RX) 330. A signal is to be transmitted to the high-voltage isolator 320 by the transmitter 310, and then received by the receiver 330. The high voltage between two ends may be isolated by the high-voltage isolator 320 so as to provide protection. As shown in FIG. 5, the digital isolation apparatus is utilized for transmission of a single-ended signal.

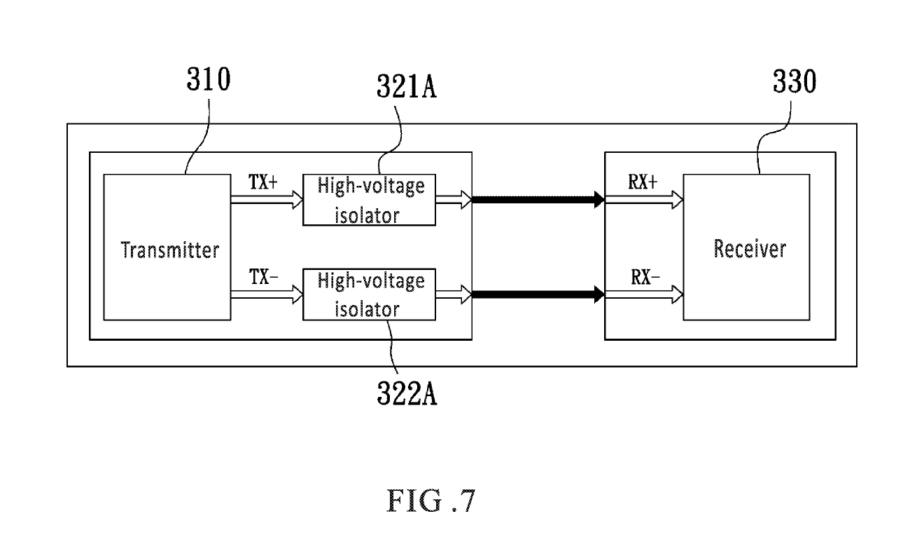

Referring to FIG. 6, in an embodiment, a digital isolation apparatus includes at least two high-voltage isolators 321 and 322 provided for transmission of differential signals, wherein the differential signals can have better resistance to common mode interference. For example, a transmitter 310 outputs differential signals denoted by TX+ and TX− and, accordingly, the high-voltage isolators 321 and 322 output differential signals denoted by RX+ and RX− to a receiver 330. In addition, the transmission of differential signals in FIGS. 7 to 9 is similar to that of FIG. 6 and their details will not be repeated for the sake of brevity.

In another embodiment as illustrated in FIG. 7, a digital isolation apparatus includes two chips for the realization of a transmitter 310 and a receiver 330, and the two chips are electrically coupled by way of bonding wires. The high-voltage isolators 321A and 322A may be implemented in the chip for the transmitter 310 for providing voltage withstanding protection.

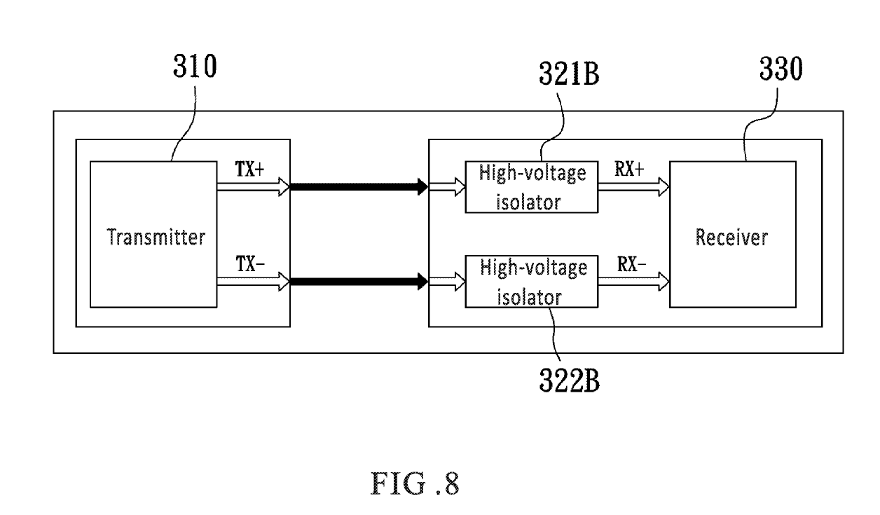

In an embodiment as illustrated in FIG. 8, the chips for a transmitter 310 and a receiver 330 are electrically coupled through bonding wires. The high-voltage isolators 321B and 322B may be implemented in the chip for the receiver 320 for providing voltage withstanding protection.

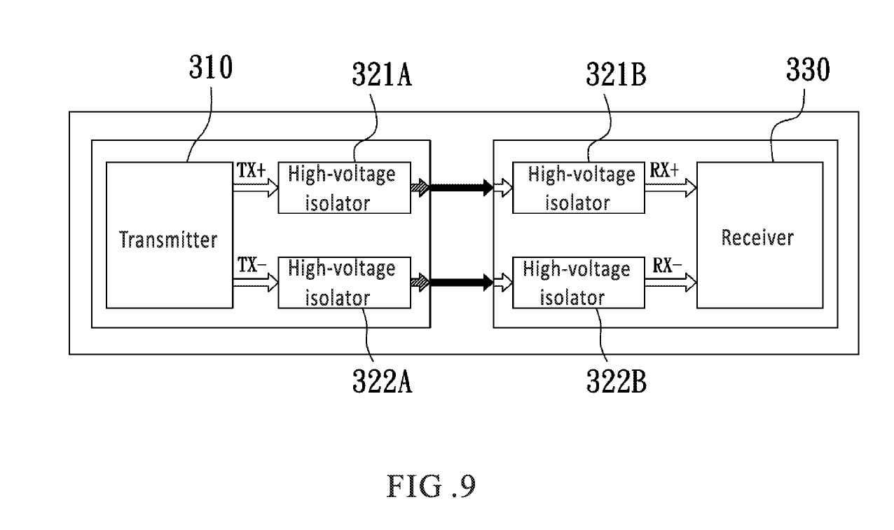

In another embodiment as illustrated in FIG. 9, the chips for a transmitter 310 and a receiver 330 of a digital isolation apparatus are equipped with high-voltage isolators, respectively. For example, the transmitter 310 has its output terminals connected to high-voltage isolators 321A and 322A; and high-voltage isolators 321B and 322B are connected to the receiver 320. The chips for the transmitter 310 and the receiver 330 may be electrically coupled through bonding wires. The digital isolation apparatus as shown in FIG. 9 may be applied in a situation where the high-voltage isolators are required to have higher voltage withstanding capability. Compared with the withstanding voltage of the high-voltage isolator in FIG. 7 or FIG. 8, the withstanding voltage of the signal transmission path from the transmitter 310 to the receiver 330 in FIG. 9 may be increased by two times from the original HV to 2HV, where HV indicates the withstanding voltage of high-voltage isolator. In addition, any of the digital isolation apparatuses shown in FIG. 5 to FIG. 9 may be implemented as a chip.

In addition, any embodiment of the high-voltage capacitor structure according to the invention may further applicable to other circuits or systems, such as surge protectors, and particularly, for example, transient-voltage-suppression (TVS) surge protectors. However, the implementation of the invention is not restricted by these examples. That is, any circuit to which the high-voltage capacitor structure according to the invention is applied may be regarded as one implementation of the invention.

As depicted above, the embodiments of the high-voltage capacitor structure have the following advantages. A high-voltage isolation and withstanding capacitor structure may be implemented based on any of the above embodiments of the high-voltage capacitor structure by using lower-complexity process, thus improving the manufacturing efficiency and design flexibility, and reducing the production cost. The high-voltage capacitor structure may be further integrated in a digital isolation apparatus such that the digital isolation apparatus may be implemented with greatly reduced manufacturing complexity, improved production efficiency and design flexibility, and reduced production cost.

While the present disclosure has been described by means of specific embodiments, numerous modifications and variations could be made thereto by those skilled in the art without departing from the scope and spirit of the present disclosure set forth in the claims.

What is claimed is:

1. A high-voltage capacitor structure, comprising:
a capacitor, the capacitor including:
a substrate;
a field oxidation layer, disposed above the substrate;
an active region, disposed above the substrate or in the substrate;
a dielectric layer, disposed above the active region and the field oxidation layer;
a passivation layer, disposed above the dielectric layer; and
a metal layer, disposed above the passivation layer;
wherein the metal layer and the active region serve as a first electrode and a second electrode of the capacitor, respectively, wherein the active region is disposed below the dielectric layer, the field oxidation layer has at least one opening, and the active region is disposed in a location of the substrate corresponding to one of the at least one opening; and
wherein no source region and no drain region are disposed correspondingly in the at least one opening of the field oxidation layer and the active region includes no source region and no drain region.

2. The high-voltage capacitor structure according to claim 1, wherein the active region is disposed on a portion of the substrate which corresponds to the one of the at least one opening of the field oxidation layer, and the active region is not a well region.

3. The high-voltage capacitor structure according to claim 1, wherein the active region is a well region in the substrate, the well region has a dopant impurity of a first conductivity type, the substrate is a substrate of a second conductivity type, and the first conductivity type is opposite to the second conductivity type.

4. The high-voltage capacitor structure according to claim 1, wherein the high-voltage capacitor structure further includes a signal electrode, electrically connected to the active region.

5. The high-voltage capacitor structure according to claim 1, wherein the dielectric layer is a first dielectric layer, the high-voltage capacitor structure further includes a second dielectric layer, the second dielectric layer is disposed above the first dielectric layer.

6. The high-voltage capacitor structure according to claim 1, wherein the dielectric layer is an inter-metal dielectric layer or inter-layer dielectric layer.

7. The high-voltage capacitor structure according to claim 1, wherein the passivation layer has a thickness greater than that of the dielectric layer.

8. The high-voltage capacitor structure according to claim 1, wherein the metal layer has a thickness of greater than 2 μm.

9. A digital isolation apparatus, comprising:
at least one high-voltage isolator, each of the at least one high-voltage isolator comprising a high-voltage capacitor structure including:
a capacitor, the capacitor including:
a substrate;
a field oxidation layer, disposed above the substrate;
an active region, disposed above the substrate or in the substrate;
a dielectric layer, disposed above the active region and the field oxidation layer;
a passivation layer, disposed above the dielectric layer; and
a metal layer, disposed above the passivation layer;
wherein the metal layer and the active region serve as a first electrode and a second electrode of the capacitor, respectively, wherein the active region is disposed below the dielectric layer, the field oxidation layer has at least one opening, and the active region is disposed in a location of the substrate corresponding to one of the at least one opening;
wherein no source region and no drain region are disposed correspondingly in the at least one opening of the field oxidation layer and the active region includes no source region and no drain region.

10. The digital isolation apparatus according to claim 9, wherein the active region is disposed on a portion of the substrate which corresponds to the one of the at least one opening of the field oxidation layer, and the active region is not a well region.

11. The digital isolation apparatus according to claim 9, wherein the active region is a well region in the substrate, the well region has a dopant impurity of a first conductivity type, the substrate is a substrate of a second conductivity type, and the first conductivity type is opposite to the second conductivity type.

12. The digital isolation apparatus according to claim 9, wherein the capacitor further includes a signal electrode, electrically coupled to the active region.

13. The digital isolation apparatus according to claim 9, wherein the dielectric layer is a first dielectric layer, the high-voltage capacitor structure further includes a second dielectric layer, and the second dielectric layer is disposed above the first dielectric layer.

14. The digital isolation apparatus according to claim 9, wherein the dielectric layer is an inter-metal dielectric layer or inter-layer dielectric layer.

15. The digital isolation apparatus according to claim 9, wherein the passivation layer has a thickness greater than that of the dielectric layer.

16. The digital isolation apparatus according to claim 9, wherein the metal layer has a thickness of greater than 2 μm.

17. The digital isolation apparatus according to claim 9, wherein number of the at least one high-voltage isolator included in the digital isolation apparatus is plural, and at least two of the high-voltage isolators are provided for transmission of differential signals.

18. The digital isolation apparatus according to claim 15, wherein the thickness of the passivation layer is greater than 2 μm.

19. The high-voltage capacitor structure according to claim 7, wherein the thickness of the passivation layer is greater than 2 μm.
